(19) United States
(12) Patent Application Publication
(10) Pub. No.: US 2007/0207393 A1
(43) Pub. Date: Sep. 6, 2007

(54) Photomask formation method, photomask, and semiconductor device fabrication method

(76) Inventor: Osamu Ikenaga, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/712,367

(22) Filed: Mar. 1, 2007

(30) Foreign Application Priority Data
Mar. 2, 2006 (JP) 2006-056432

(51) Int. Cl. G03F 1/00; G03C 5/00; G06K 9/00

(52) U.S. Cl. 430/5; 382/144; 430/30

(57) ABSTRACT

According to an aspect of the invention, there is provided a photomask formation method including forming, on a photomask, a pattern obtained by coding information including inspection information for inspecting the photomask and an information attribute which identifies a type of the inspection information; reading the inspection information from the pattern; and inspecting the photomask on the basis of the read inspection information.

### CROSS-REFERENCE TO RELATED APPLICATIONS

This application is based upon and claims the benefit of priority from prior Japanese Patent Application No. 2006-056432, filed Mar. 2, 2006, the entire contents of which are incorporated herein by reference.

### BACKGROUND OF THE INVENTION

1. Field of the Invention

The present invention relates to a method of forming a photomask for use in the fabrication of a semiconductor device, a photomask, and a semiconductor device fabrication method.

2. Description of the Related Art

### FIRST BACKGROUND ART

A photomask for use in the semiconductor device fabrication process undergoes defect inspection during the course of manufacture. One photomask defect inspection method (first comparison method) checks whether a pattern is formed as desired on a photomask by comparing the pattern formed on the photomask with mask inspection data formed on the basis of design data or mask drawing data used in the formation of the photomask. Another defect inspection method (second comparison method) extracts identical patterns from patterns formed on a photomask, and inspects the presence/absence of a defect by comparing the extracted patterns. On the basis of these inspection results, whether a detected defect portion can be repaired is checked, and a photomask is formed through a step of repairing the defect if necessary.

To perform the photomask defect inspection described above, a mask formation requesting department provides a mask formation department with mask inspection information complying with a document or predetermined format by computer communication before mask formation. Of these pieces of information concerning the mask defect inspection, on the basis of inspection area information for selectively extracting an inspection area from a photomask as an object of inspection, and inspection sensitivity information and inspection method (the first or second comparison method described above) information corresponding to the selectively extracted inspection area, the mask formation department obtains, by conversion, control information (an inspection recipe) for allowing a mask defect inspection apparatus to perform inspection meeting the designation, or an operator forms the inspection recipe, thereby preparing for the mask defect inspection. The correctness and the presence/absence of a defect of a pattern formed on a photomask is inspected by controlling the mask defect inspection apparatus on the basis of the inspection recipe.

However, the photomask defect inspection method described above has the following problems. That is, as information for forming a photomask for use in the fabrication of a semiconductor device, the method requires drawing data expressing a desired pattern to be formed on the photomask, and mask inspection information for verifying whether a mask pattern is correctly formed from the drawing data and whether there is a defect. In addition, preparations for mask fabrication are necessary to obtain a uniform fabrication flow in mask fabrication steps. For example, the mask defect inspection information from the mask fabrication requesting department must be converted into a predetermined ruled format. This interferes with TAT (Turn Around Time) reduction in mask fabrication. The interference in TAT reduction prevents labor saving in mask fabrication and the reduction in mask fabrication cost.

Also, whenever a remake mask (the remake of a mask fabricated in the past) is fabricated, the fabrication requires mask inspection information including drawing data of the original mask, inspection area information for selectively extracting an inspection area from a photomask as an object of inspection, and inspection sensitivity information and inspection method (the first or second comparison method described above) information corresponding to the selectively extracted inspection area. Furthermore, these pieces of mask inspection information complicate because demands for increasing the inspection sensitivity are becoming even severer as micropatterning advances. Accordingly, an infrastructure for holding and managing these data and information and human resources for management and practical use are necessary. This interferes with labor saving in mask fabrication and mask cost reduction, and becomes a serious problem which prevents the reduction in mask fabrication cost.

### SECOND BACKGROUND ART

Whether a pattern formed on a photomask for use in the semiconductor device fabrication process is formed as desired is determined by measuring a mask pattern dimension extracted by a desired rule, and comparing the measurement result with a dimensional error range allowed for the mask.

In the above determination, a mask formation requesting department provides a mask formation department with mask dimension guarantee information complying with a document or predetermined format by computer communication before mask formation. From the mask dimension guarantee information, the mask formation department extracts information concerning a dimension monitor pattern portion required for dimension acceptability determination, and converts the extracted information into control information (a measurement recipe) for allowing a dimension measurement apparatus to measure the dimension, or an operator forms the measurement recipe, thereby preparing for dimension measurement.

Meanwhile, a document or information as an acceptability determination criterion for the measurement result obtained by the dimension measurement apparatus is exchanged between the mask formation requesting department and mask formation department similarly to the mask dimension guarantee information, thereby preparing for determination of the acceptability of a mask formed by the mask formation department. A desired pattern is formed on the basis of drawing data expressing the desired pattern through a drawing step represented by an electron beam lithography apparatus, and pattern formation steps including a development step and etching step. The dimension of the desired pattern is measured on the basis of the measurement recipe generated from the mask dimension guarantee information, and whether the measurement result satisfies the required acceptability determination criterion is checked.

However, the above photomask dimension assuring method has the following problems. That is, as information for forming a photomask for use in the fabrication of a semiconductor device, the method requires drawing data expressing a desired pattern to be formed on the photomask, pattern measurement information for verifying whether a mask pattern formed from the drawing data is finished with the required desired accuracy, and dimension acceptability determination information for determining whether the pattern measurement result satisfies the required formation accuracy. In addition, preparations for mask fabrication are necessary to obtain a uniform fabrication flow in mask fabrication steps. For example, the pattern measurement information and dimension acceptability determination information from the mask fabrication requesting department must be converted into a predetermined ruled format. This interferes with TAT reduction in mask fabrication. The interference in TAT reduction prevents labor saving in mask fabrication and the reduction in mask fabrication cost.

Also, the fabrication of a remake mask (the remake of a mask fabricated in the past) requires drawing data of the original mask, pattern measurement information or a measurement recipe formed from the information, and dimension acceptability determination information. Therefore, an infrastructure for holding and managing these data and information and human resources for management and practical use are necessary. This interferes with labor saving in mask fabrication and mask cost reduction, and becomes a serious problem which prevents the reduction in mask fabrication cost.

### THIRD BACKGROUND ART

Whether a pattern formed on a photomask for use in the semiconductor device fabrication process is formed as desired is determined by measuring a mask pattern position extracted by a desired rule, and comparing the measurement result with the allowable error range of the mask.

In the above determination, a mask formation requesting department provides a mask formation department with mask positional accuracy guarantee information complying with a document or predetermined format by computer communication before mask formation. From the mask positional accuracy guarantee information, the mask formation department extracts information concerning a positional accuracy monitor pattern portion required to determine the acceptability of the positional accuracy, and converts the extracted information into control information (a measurement recipe) for allowing a positional accuracy measurement apparatus to measure the positional accuracy, or an operator forms the measurement recipe, thereby preparing for pattern positional accuracy measurement.

Meanwhile, a document or information as an acceptability determination criterion for the measurement result obtained by the positional accuracy measurement apparatus is exchanged between the mask formation requesting department and mask formation department similarly to the positional accuracy guarantee information, thereby preparing for determination of the acceptability of a mask formed by the mask formation department. A desired pattern is formed on the basis of drawing data expressing the desired pattern through a drawing step represented by an electron beam lithography apparatus, and pattern formation steps including a development step and etching step. The positional accuracy of the desired pattern is measured on the basis of the measurement recipe generated from the positional accuracy guarantee information, and whether the measurement result satisfies the required acceptability determination criterion is checked.

However, the above photomask positional accuracy assuring method has the following problems. That is, as information for forming a photomask for use in the fabrication of a semiconductor device, the method requires drawing data expressing a desired pattern to be formed on the photomask, pattern positional accuracy measurement information for verifying whether a mask pattern formed from the drawing data is finished with the required desired accuracy, and positional accuracy acceptability determination information for determining whether the pattern measurement result satisfies the required formation accuracy. In addition, preparations for mask fabrication are necessary to obtain a uniform fabrication flow in mask fabrication steps. For example, the pattern positional accuracy information and positional accuracy acceptability determination information from the mask fabrication requesting department must be converted into a predetermined ruled format. This interferes with TAT reduction in mask fabrication. The interference in TAT reduction prevents labor saving in mask fabrication and the reduction in mask fabrication cost.

Also, the fabrication of a remake mask (the remake of a mask fabricated in the past) requires drawing data of the original mask, pattern positional accuracy measurement information or a measurement recipe formed from the information, and positional accuracy acceptability determination information. Therefore, an infrastructure for holding and managing these data and information and human resources for management and practical use are necessary. This interferes with labor saving in mask fabrication and mask cost reduction, and becomes a serious problem which prevents the reduction in mask fabrication cost.

Note that Jpn. Pat. Appln. KOKAI Publication No. 2002-231613 describes a method which uses a mask having a reduced code with a shape obtained by reducing a barcode, which is formed by intermittently arranging a plurality of element codes in accordance with a predetermined system, in a direction perpendicular to a barcode reading direction (element code arranging direction). This method transfers an image of the reduced code onto a substrate a plurality of times by exposure such that the images are adjacent to each other in the direction perpendicular to the barcode reading direction.

### BRIEF SUMMARY OF THE INVENTION

According to an aspect of the present invention, there is provided a photomask formation method comprising: forming, on a photomask, a pattern obtained by coding information including inspection information for inspecting the photomask and an information attribute which identifies a type of the inspection information; reading the inspection information from the pattern; and inspecting the photomask on the basis of the read inspection information.

According to another aspect of the present invention, there is provided a photomask comprising a pattern obtained by coding information including inspection information for inspecting the photomask and an information attribute which identifies a type of the inspection information.

According to another aspect of the present invention, there is provided a semiconductor device fabrication method of fabricating a semiconductor device by reading inspection information from a pattern formed on a photomask, the pattern being obtained by coding information including the inspection information for inspecting the photomask and an information attribute which identifies a type of the inspection information, and forming a circuit pattern on a semiconductor substrate by using the photomask inspected on the basis of the read inspection information.

### BRIEF DESCRIPTION OF THE SEVERAL VIEWS OF THE DRAWING

FIG. 1 is a flowchart showing the formation steps of a photomask for use in the fabrication of a semiconductor device according to the first embodiment;

FIG. 2 is a plan view showing the pattern image of the photomask according to the first embodiment;

FIG. 3 is a schematic view showing the system of mask drawing data according to the first embodiment;

FIG. 4 is a plan view showing the arrangement of two-dimensional barcodes according to the first embodiment;

FIG. 5 is a view showing an example of mask defect inspection information expressed by a two-dimensional barcode portion according to the first embodiment;

FIG. 6 is a view showing the arrangement of a mask defect inspection apparatus according to the first embodiment;

FIG. 7 is a view showing the system of mask defect inspection according to the first embodiment;

FIG. 8 is a flowchart showing the fabrication steps of a photomask for use in the fabrication of a semiconductor device according to the second embodiment;

FIG. 9 is a plan view showing the pattern image of the photomask according to the second embodiment;

FIG. 10 is a schematic view showing the system of mask drawing data according to the second embodiment;

FIG. 11 is a plan view showing the arrangement of two-dimensional barcodes according to the second embodiment;

FIG. 12 is a view showing the system of pattern measurement information expressed by a two-dimensional barcode portion according to the second embodiment;

FIGS. 13A, 13B, and 13C are views showing measurement pattern shapes according to the second embodiment;

FIG. 14 is a view showing the image of critical pattern extraction according to the second embodiment;

FIG. 15 is a flowchart showing the fabrication steps of a photomask for use in the fabrication of a semiconductor device according to the third embodiment;

FIG. 16 is a plan view showing the pattern image of the photomask according to the third embodiment;

FIG. 17 is a schematic view showing the system of mask drawing data according to the third embodiment;

FIG. 18 is a plan view showing the arrangement of two-dimensional barcodes according to the third embodiment;

FIGS. 19A, 19B, and 19C are respectively a view showing the system of positional accuracy measurement information expressed by a two-dimensional barcode portion according to the third embodiment, a view showing an example of a measurement mark, and a view showing a measurement position coordinate system on the mask; and

FIG. 20 is a view showing the image of derivation of the pattern positional accuracy according to the third embodiment.

### DETAILED DESCRIPTION OF THE INVENTION

Embodiments of the present invention will be explained below with reference to the accompanying drawing.

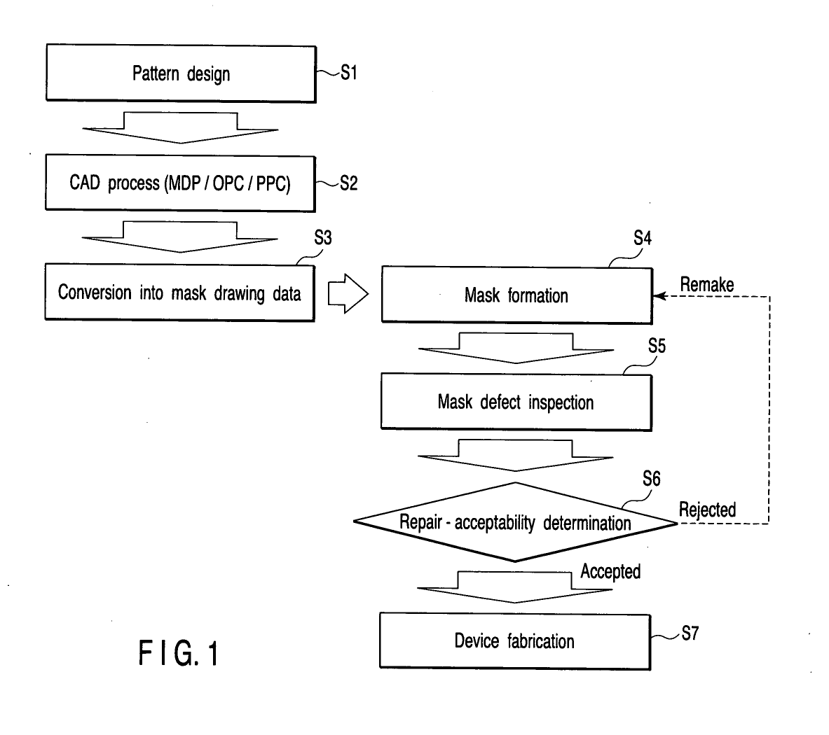

FIG. 1 is a flowchart showing the formation steps of a photomask for use in the fabrication of a semiconductor device according to the first embodiment of the present invention. The following steps include a mask defect inspection step of inspecting the correctness and the presence/absence of a defect of a pattern formed on the photomask.

First, in step S1, design data is formed by designing a desired pattern for fabricating a semiconductor device. In step S2, a CAD process is performed on the design data. This CAD process is a combination of, e.g., optical proximity effect correction (to be referred to as an OPC process hereinafter) for correcting the optical proximity effect (to be referred to as the OPE hereinafter) when an exposure apparatus transfers the pattern from a photomask onto a wafer, a PPC process for correcting pattern deformation of the wafer caused by the process proximity effect (to be referred to as the PPE hereinafter) which occurs when the exposed pattern is processed by development and etching, an interlayer data operating process (e.g., an AND or OR operation between graphic data) for obtaining pattern data to be formed on a photomask from the design data, a dimension correcting process (to be referred to as resizing hereinafter), and a tone reversing process. In this manner, data of the desired pattern to be formed on a photomask is formed.

In step S3, the data of the desired pattern to be formed on a photomask is converted into mask drawing data which can be input to a pattern drawing (generating) apparatus represented by an electron beam lithography apparatus for use in the fabrication of a mask.

In step S4, the mask drawing data is input to a pattern drawing apparatus represented by an electron beam lithography apparatus to draw the desired pattern on a mask substrate, and the mask substrate on which the pattern is drawn is processed by a mask processing step mainly including development and etching, thereby forming the desired pattern. After that, to check whether the pattern formed on the mask satisfies the required accuracy, the dimensions of selectively extracted monitor patterns are measured. Whether the results of the dimension measurements satisfy the dimensional accuracy required of the mask is determined. Following the same procedures as above, the positional accuracy of a selectively extracted monitor pattern portion is measured, and whether the result of the positional accuracy measurement satisfies the required positional accuracy is determined. A product having passed these determinations is transferred to a mask defect inspection step shown in step S5.

In this mask defect inspection step, whether the pattern is formed as desired is inspected at a predetermined inspection sensitivity. In step S6, a detected defective portion undergoes a repairing step, and the repair accuracy of the repaired defective portion is finally monitored to determine the acceptability of the mask. In step S7, a pellicle is adhered to the mask having passed the inspection, and the mask is shipped to a device fabrication site where a semiconductor device is fabricated by using the mask. The mask is rejected, however, if it is determined that the original pattern portion is destroyed to such an extent that it cannot be repaired in the mask defect inspection step or repairing step, or if it is determined that the mask cannot be well repaired because a portion which cannot be repaired at the desired accuracy remains when the defective portion detected in the mask defect inspection step is repaired. In this case, the series of mask formation steps starting from the pattern drawing step are repeated.

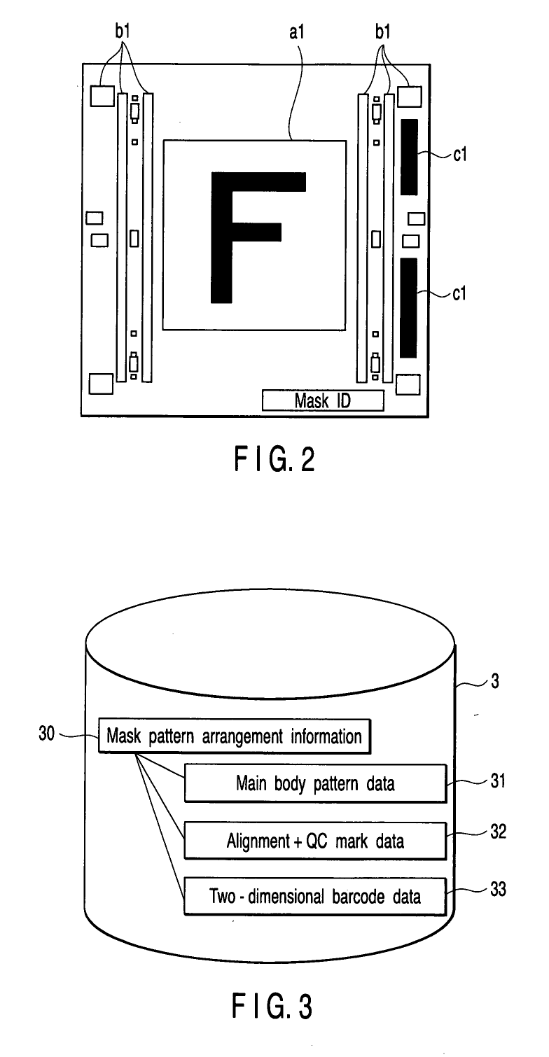

FIG. 2 is a plan view showing the pattern image of the photomask formed by the above steps. Referring to FIG. 2, a portion describing an F mark is an area a1 expressing a desired semiconductor device pattern. An area b1 includes an alignment mark necessary to transfer the photomask formed by the above steps to a semiconductor wafer by an exposure apparatus, and QC marks for monitoring the pattern accuracy independent of a semiconductor device pattern which changes in accordance with a mask. A portion indicated by an area c1 is a two-dimensional barcode formation portion expressing pattern measurement information and dimension acceptability determination information as the gist of this embodiment.

FIG. 3 is a schematic view showing the system of mask drawing data expressing these patterns to be formed on the photomask. As shown in FIG. 3, a disk 3 separately stores main body pattern data 31 expressing the semiconductor device pattern described above, alignment mark and QC mark data 32, and two-dimensional barcode data 33. These pattern data are defined in association with mask pattern arrangement information 30 expressing the drawing positions on the mask.

The two-dimensional barcode data portion will be explained below.

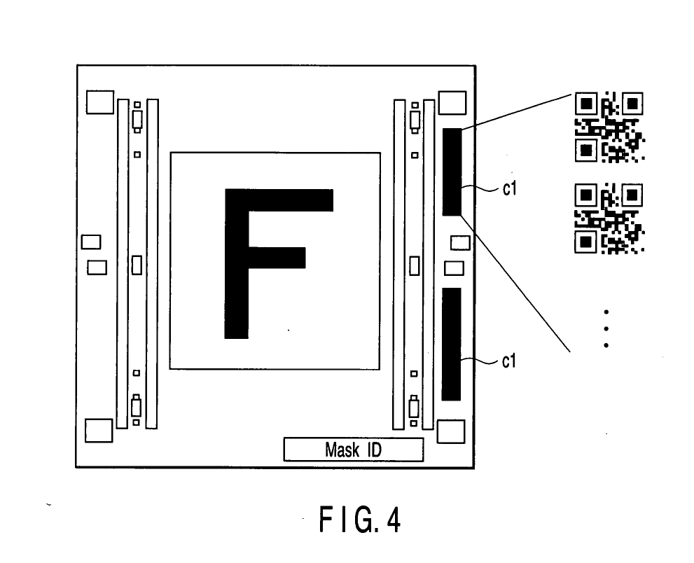

FIG. 4 is a plan view showing the arrangement of two-dimensional barcodes. Referring to FIG. 4, the areas cl are set as two-dimensional barcode formation areas. The number of characters expressible by one two-dimensional barcode is limited. Therefore, if information cannot be expressed by one two-dimensional barcode or information attributes to be expressed by a two-dimensional barcode are different, a plurality of two-dimensional barcodes are arranged as they are separately defined. When information is expressed by a plurality of two-dimensional barcodes, the information is expressed by this information attribute. Information expressed by this two-dimensional barcode will be explained below.

An information system expressed by a two-dimensional barcode includes (1) attribute information representing the information attribute described above, and (2) real data expressing inspection area definition information, inspection sensitivity information, and inspection comparison method information. Examples of the real data are inspection information such as measurement mark position information, measurement mark width information, and measurement mark tone information.

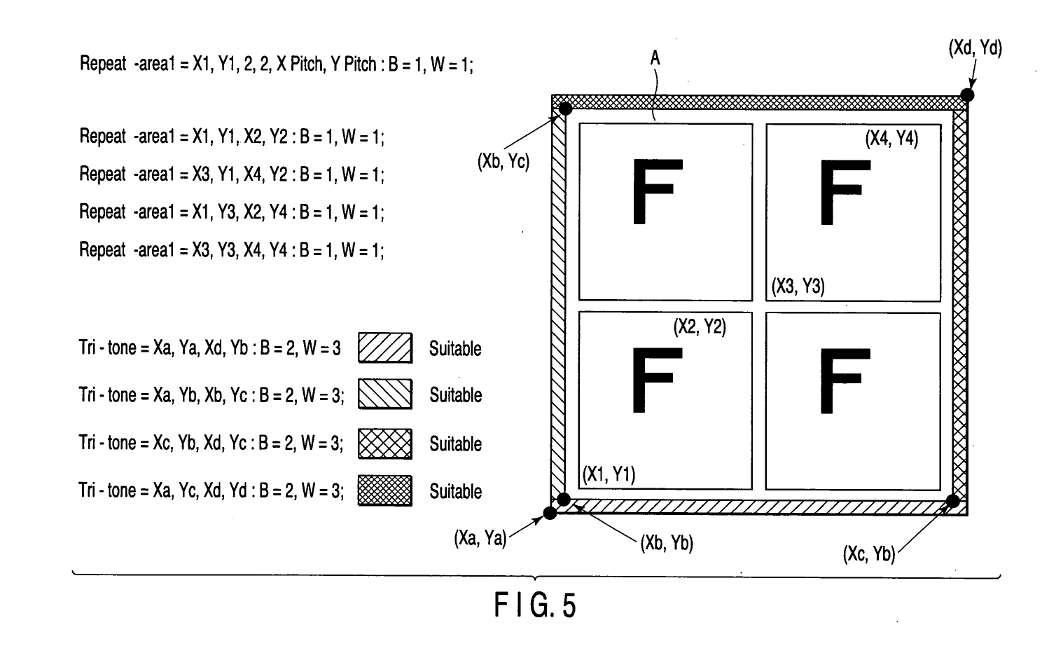

FIG. 5 is a view showing an example of mask defect inspection information expressed by the two-dimensional barcode portion. Referring to FIG. 5, “Repeat-areal” describes an area formed by identical patterns, and “Repeat-area1=X1, Y1, 2, 2, X pitch, Y pitch” is a description expressing the repetitive structure of patterns in a unit area A. As another expression form, the area can also be expressed by “Repeat-area1=X1, Y1, X2, Y2;” to “Repeat-area1=X3, Y3, X4, Y4;”.

In this expression, the numerical part of areal means the identification of identical patterns; different numerals mean different reference patterns. Also, hatched portions and halftone portions in FIG. 5 indicate, as patterns contained in the area, tri-tone areas formed by at least three types of portions, i.e., a glass portion corresponding to a light-transmitting portion, a halftone pattern portion made of a semitransparent film which transmits part of light, and a light-shielding film portion made of a light-shielding film which shields light. The tri-tone areas are expressed by “Tri-tone=Xa, Ya, Xd, Yb;” to “Tri-tone=Xa, Yc, Xd, Yd;”.

Furthermore, “B=1, W=1;” defined in the end of each descriptive line indicates the inspection sensitivity of an area corresponding to the line definition. B=1 defines the inspection sensitivity for a black defect, W=1 defines that for a white defect, and the numerical part distinguishes between the inspection sensitivities. The information related to mask defects as described is formed as two-dimensional barcode patterns in a portion of a photomask, and the inspection information defined in the two-dimensional barcodes is read and recognized in the mask defect inspection step. Then, an inspection recipe for controlling a mask defect inspection apparatus (to be described later) is formed, and desired mask defect inspection is performed on the basis of the inspection recipe.

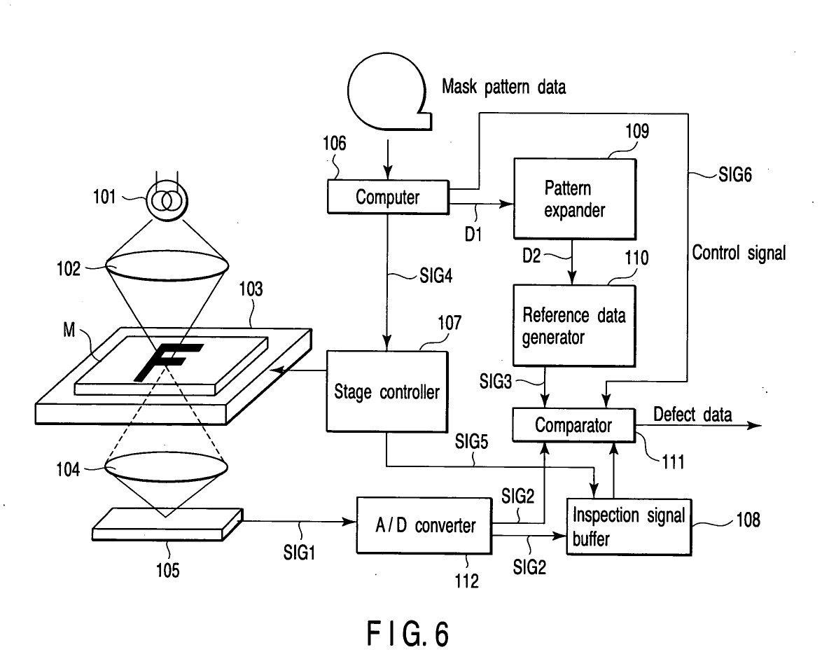

FIG. 6 is a block diagram showing the arrangement of a mask defect inspection apparatus.

In FIG. 6, reference numeral 103 denotes an X-Y stage on which a mask M for use in the fabrication of a semiconductor device is placed. A stage controller 107 having received an instruction from a computer 106 drives the X-Y stage 103 in the X direction (the horizontal direction in the paper) and the Y direction (the vertical direction in the paper).

A laser interferometer (not shown) monitors the position of the X-Y stage 103. Information of the monitored position of the X-Y stage 103 is input to the stage controller 107. On the basis of the input position information, the stage controller 107 highly accurately controls the X-Y stage 103 on which the mask M is placed.

A light source 101 is positioned above the X-Y stage 103. Light emitted from the light source 101 irradiates the mask M placed on the X-Y stage 103. Light transmitted through the mask M forms an image on the light-receiving surface of an image sensing device 105 represented by a CCD sensor. The image sensing device 105 has, e.g., a plurality of light-receiving sensors arranged in a line.

While the mask M is irradiated with the light, the X-Y stage 103 is continuously moved in the direction (Y direction) perpendicular to the reading direction (X direction) of the sensors of the image sensing device 105. Consequently, the image sensing device 105 detects a detection signal (detection analog signal) SIG1 corresponding to the mask pattern of the mask M. The detection signal SIG1 corresponds to the mask pattern dimensions or the like.

An A/D converter 112 converts the detection analog signal SIG1 into a digital signal (detection digital signal) SIG2 in accordance with an instruction from the computer 106, and outputs the detection digital signal SIG2 to a comparator 111. The detection digital signal SIG2 is stored in an inspection signal buffer 108.

Meanwhile, mask pattern data (pattern design data) as the basis of formation of a mask pattern to be inspected is input to the computer 106. The computer 106 outputs mask pattern data D1 to a pattern expander 109.

The pattern expander 109 expands the mask pattern data D1 into expanded data D2, and outputs the expanded data D2 to a reference data generator 110.

The reference data generator 110 forms a reference digital signal SIG3 by converting the mask pattern data of an area corresponding to the detection signal SIG1 detected by the image sensing device 105 into a signal format which can be compared with the detection digital signal SIG2. The reference data generator 110 outputs the reference digital signal SIG3 to the comparator 111.

On the basis of an instruction from the computer 106, the comparator 111 compares the detection digital signal SIG2 with the reference digital signal SIG3 in accordance with an appropriate algorithm. If the two signals do not match, the comparator 111 determines that there is a pattern defect, and outputs defect data.

The mask pattern formed on the mask M is inspected by repeating the series of defect inspection processes described above, i.e., by repetitively performing the scanning operation of the image sensing device 105 and the continuous movement of the X-Y stage 103 on which the mask M is placed, and comparing the detection digital signal SIG2 in a desired area on the mask M with the reference digital signal SIG3.

The above explanation corresponds to defect inspection not using the detection digital signal SIG2 stored in the inspection signal buffer 108, i.e., corresponds to die-to-database comparison type defect inspection.

On the other hand, die-to-die comparison type defect inspection uses the detection digital signal SIG2 stored in the inspection signal buffer 108.

That is, following the same procedures as above, while the X-Y stage 103 on which the mask M is placed is continuously moved in the X direction (the horizontal direction in the paper), the light-receiving sensors of the image sensing device 105 are scanned in the Y direction (the vertical direction in the paper) perpendicular to the moving direction of the X-Y stage 103, thereby obtaining a detection analog signal SIG1 (to be referred to as a first detection analog signal SIG1 hereinafter) corresponding to an area formed by identical patterns including repetitive patterns formed on the mask M. The A/D converter 112 converts the first detection analog signal SIG1 into a digital signal SIG2 (to be referred to as a first detection digital signal SIG2 hereinafter).

In addition, a detection analog signal SIG1 (to be referred to as a second detection analog signal SIG1 hereinafter) corresponding to a pattern area different from the above pattern area is obtained. The A/D converter 112 converts the second detection analog signal SIG1 into a digital signal SIG2 (to be referred to as a second detection digital signal SIG2 hereinafter).

On the basis of a control signal SIG6 (instruction) from the computer 106, the comparator 111 receives the second detection digital signal SIG2, reads out the first detection digital signal SIG2 stored in the inspection signal buffer 108, and compares the first detection digital signal SIG2 with the second detection digital signal SIG2, thereby inspecting a difference between the two partial areas.

If there is a difference, the comparator 111 determines that there is a pattern defect, and outputs defect data. If there is no difference, the comparator 111 determines that there is no pattern defect, and outputs no-defect data.

After that, defect inspection is performed in the whole pattern area having identical patterns on the mask M by repeating a series of steps including a step of moving the X-Y stage 103 step by step by the scan width detected by the image sensing device 105 in the continuous movement direction X and the direction Y perpendicular to the direction X, and a step of performing the defect inspecting operation described above.

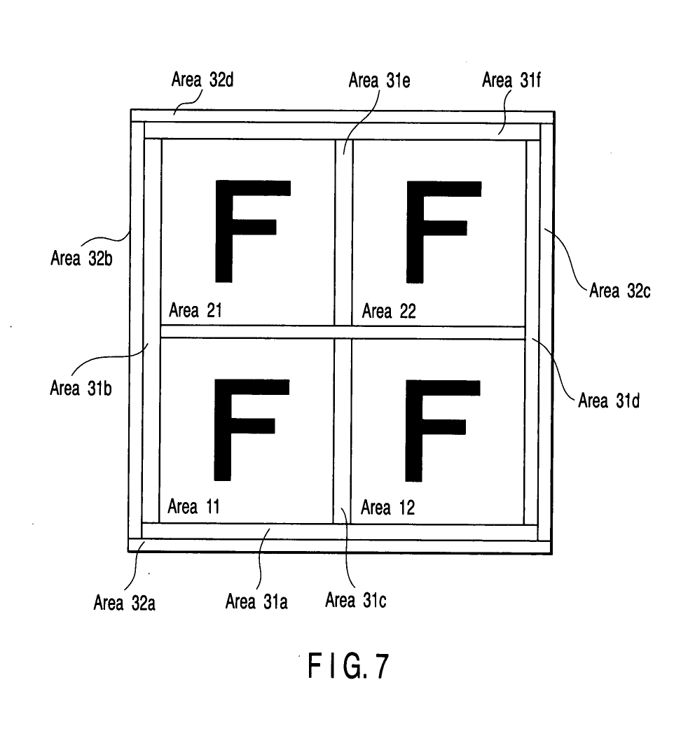

FIG. 7 is a view showing the system of mask defect inspection according to this embodiment. First, on the basis of the repeat information defined by “Repeat-area”, patterns formed in areas 11 and 12 on a mask shown in FIG. 7 are inspected by the die-to-die method indicated by the inspection comparison method information. If the inspection sensitivity determined from the pattern shape to be inspected or the inspection sensitivity of an inspection apparatus does not satisfy the desired sensitivity, defect inspection is performed in the areas 11 and 12 at a highest sensitivity unique to the inspection apparatus. Following the same procedures as above, defect inspection is performed in areas 21 and 22 shown in FIG. 7 by the die-to-die method.

Then, defect inspection is performed in areas 31a to 31f shown in FIG. 7 by using the mask defect inspection apparatus shown in FIG. 6 by die-to-database comparison which detects a defect by comparing a mask pattern detection signal obtained on the basis of a pattern formed on a mask with a reference signal, which is indicated by the inspection comparison method information, formed from mask data used when forming the pattern on the mask. If a most strict inspection sensitivity of patterns included in the inspection areas 31a to 31f or the inspection sensitivity of the inspection apparatus does not satisfy the desired sensitivity, inspection is performed at a highest sensitivity unique to the inspection apparatus.

In addition, areas 32a to 32d shown in FIG. 7 positioned outside the areas 31a to 31f indicate, as patterns contained in the areas, tri-tone areas formed by at least three types of portions, i.e., a glass portion corresponding to a light-transmitting portion, a halftone pattern portion made of a semitransparent film, and a light-shielding film portion made of a light-shielding film which shields light. In the tri-tone areas, the inspection sensitivity determined from the contained pattern category is normally lower than those in the areas 11, 12, 21, and 22 as objects of die-to-die inspection and the areas 31a to 31f as objects of die-to-database inspection. Accordingly, defect inspection is performed in the areas 32a to 32d by die-to-database comparison by rationalizing the inspection sensitivity.

Following the series of inspection procedures as described above, defect inspection is performed on the whole desired pattern formed on the photomask at a proper inspection sensitivity.

When forming a photomask, the photomask formation method of the first embodiment forms, on the photomask, two-dimensional barcode patterns of information concerning defect inspection for inspecting the correctness and the presence/absence of a defect of a pattern formed on the photomask. In the step of inspecting a defect of a semiconductor device pattern formed on the photomask, the information concerning defect inspection of the mask is read and identified from the two-dimensional barcode portion formed as patterns on the mask. On the basis of this identification information, a designated area is inspected at a designated inspection sensitivity by a designated comparison method (the die-to-die method which compares areas formed by identical patterns formed on a mask or the die-to-database method which compares a pattern formed on a mask with mask inspection data formed on the basis of design data or mask drawing data), thereby determining the acceptability of the photomask.

Conventionally, defect inspection information which indicates a defect guarantee area and the defect inspection sensitivity, comparison method, and the like of the area and which is exchanged by a document or communicating means (e.g., computer communication) is circulated through a path different from that of a photomask as an actual fabricated product, and managed independently of the photomask.

Accordingly, if it is necessary to refabricate a once formed photomask owing to an increase in production of semiconductor devices or breakage of the photomask, information concerning defect inspection for fabrication in the past must be prepared again. This requires much labor and an infrastructure for managing the labor, and hence interferes with labor saving and process simplification in mask fabrication, resulting in a big factor of an increase in cost. Also, under the circumstances in which micropatterning is abruptly advancing, control information pertaining to defect inspection extremely complicates, so the influence of the information is more and more increasing.

In the first embodiment, however, it is possible to integrally manage drawing data necessary to form a photomask for use in the fabrication of a semiconductor device, and information concerning mask defect inspection for inspecting the correctness and the presence/absence of a defect of a pattern formed on the mask. This makes it possible to detect the information concerning mask defect inspection from two-dimensional barcodes formed on the photomask, and automatically form a control recipe for allowing a mask defect inspection apparatus to perform mask defect inspection. Consequently, it is possible to shorten the TAT, save proper inspection sensitivity.

When forming a photomask, the photomask formation method of the first embodiment forms, on the photomask, two-dimensional barcode patterns of information concerning defect inspection for inspecting the correctness and the presence/absence of a defect of a pattern formed on the photomask. In the step of inspecting a defect of a semiconductor device pattern formed on the photomask, the information concerning defect inspection of the mask is read and identified from the two-dimensional barcode portion formed as patterns on the mask. On the basis of this identification information, a designated area is inspected at a designated inspection sensitivity by a designated comparison method (the die-to-die method which compares areas formed by identical patterns formed on a mask or the die-to-database method which compares a pattern formed on a mask with mask inspection data formed on the basis of design data or mask drawing data), thereby determining the acceptability of the photomask.

Conventionally, defect inspection information which indicates a defect guarantee area and the defect inspection sensitivity, comparison method, and the like of the area and which is exchanged by a document or communicating means (e.g., computer communication) is circulated through a path different from that of a is indicated by the inspection comparison method information, formed from mask data used when forming the pattern on the mask. If a most strict inspection sensitivity of patterns included in the inspection areas 31a to 31f or the inspection sensitivity of the inspection apparatus does not satisfy the desired sensitivity, inspection is performed at a highest sensitivity unique to the inspection apparatus.

In addition, areas 32a to 32d shown in FIG. 7 positioned outside the areas 31a to 31f indicate, as patterns contained in the areas, tri-tone areas formed by at least three types of portions, i.e., a glass portion corresponding to a light-transmitting portion, a halftone pattern portion made of a semitransparent film, and a light-shielding film portion made of a light-shielding film which shields light. In the tri-tone areas, the inspection sensitivity determined from the contained pattern category is normally lower than those in the areas 11, 12, 21, and 22 as objects of die-to-die inspection and the areas 31a to 31f as objects of die-to-database inspection. Accordingly, defect inspection is performed in the areas 32a to 32d by die-to-database comparison by rationalizing the inspection sensitivity.

Following the series of inspection procedures as described above, defect inspection is performed on the whole desired pattern formed on the photomask at a proper inspection sensitivity.

When forming a photomask, the photomask formation method of the first embodiment forms, on the photomask, two-dimensional barcode patterns of information concerning defect inspection for inspecting the correctness and the presence/absence of a defect of a pattern formed on the photomask. In the step of inspecting a defect of a semiconductor device pattern formed on the photomask, the information concerning defect inspection of the mask is read and identified from the two-dimensional barcode portion formed as patterns on the mask. On the basis of this identification information, a designated area is inspected at a designated inspection sensitivity by a designated comparison method (the die-to-die method which compares areas formed by identical patterns formed on a mask or the die-to-database method which compares a pattern formed on a mask with mask inspection data formed on the basis of design data or mask drawing data), thereby determining the acceptability of the photomask.

Conventionally, defect inspection information which indicates a defect guarantee area and the defect inspection sensitivity, comparison method, and the like of the area and which is exchanged by a document or communicating means (e.g., computer communication) is circulated through a path different from that of a photomask as an actual fabricated product, and managed independently of the photomask.

Accordingly, if it is necessary to refabricate a once formed photomask owing to an increase in production of semiconductor devices or breakage of the photomask, information concerning defect inspection for fabrication in the past must be prepared again. This requires much labor and an infrastructure for managing the labor, and hence interferes with labor saving and process simplification in mask fabrication, resulting in a big factor of an increase in cost. Also, under the circumstances in which micropatterning is abruptly advancing, control information pertaining to defect inspection extremely complicates, so the influence of the information is more and more increasing.

In the first embodiment, however, it is possible to integrally manage drawing data necessary to form a photomask for use in the fabrication of a semiconductor device, and information concerning mask defect inspection for inspecting the correctness and the presence/absence of a defect of a pattern formed on the mask. This makes it possible to detect the information concerning mask defect inspection from two-dimensional barcodes formed on the photomask, and automatically form a control recipe for allowing a mask defect inspection apparatus to perform mask defect inspection. Consequently, it is possible to shorten the TAT, save manpower, and reduce the management infrastructure in mask fabrication, thereby largely reducing the mask fabrication cost.

The first embodiment can automate the mask defect inspection step and rationalize document management pertaining to mask defect inspection.

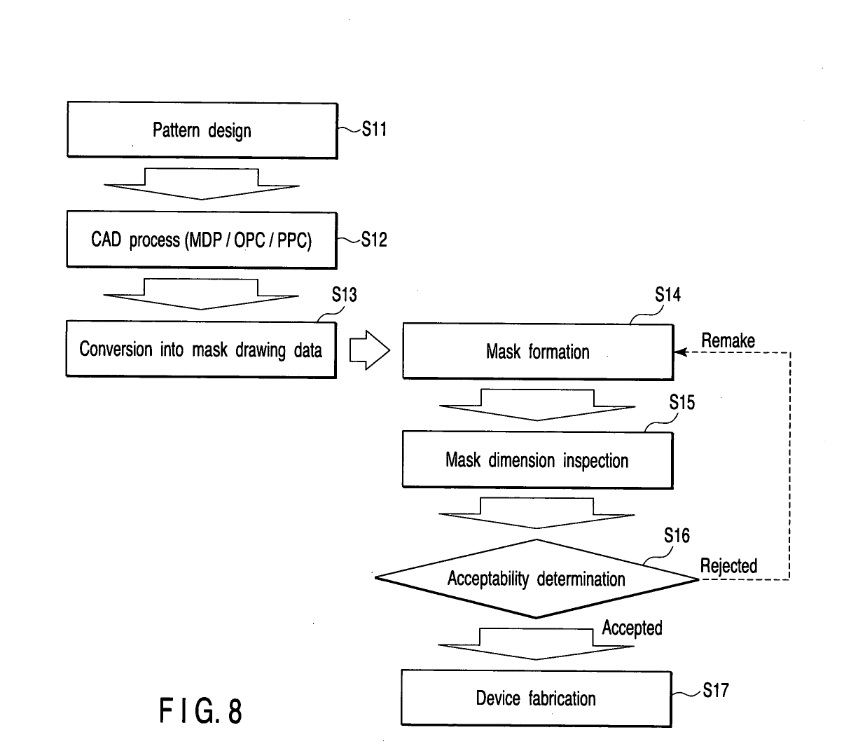

FIG. 8 is a flowchart showing the formation steps of a photomask for use in the fabrication of a semiconductor device according to the second embodiment of the present invention. The following steps include a mask dimension assuring step of inspecting whether the dimensional accuracy of a pattern formed on the photomask satisfies the desired required accuracy.

First, in step S11, design data is formed by designing a desired pattern for fabricating a semiconductor device. In step S12, a CAD process is performed on the design data. This CAD process is a combination of, e.g., optical proximity effect correction (to be referred to as an OPC process hereinafter) for correcting the optical proximity effect (to be referred to as the OPE hereinafter) when an exposure apparatus transfers the pattern from a photomask onto a wafer, a PPC process for correcting pattern deformation of the wafer caused by the process proximity effect (to be referred to as the PPE hereinafter) which occurs when the exposed pattern is processed by development and etching, an interlayer data operating process (e.g., an AND or OR operation between graphic data) for obtaining pattern data to be formed on a photomask from the design data, a dimension correcting process (to be referred to as resizing hereinafter), and a tone reversing process. In this manner, data of the desired pattern to be formed on a photomask is formed.

In step S13, the data of the desired pattern to be formed on a photomask is converted into mask drawing data which can be input to a pattern drawing (generating) apparatus represented by an electron beam lithography apparatus for use in the fabrication of a mask.

In step S14, the mask drawing data is input to a pattern drawing apparatus represented by an electron beam lithography apparatus to draw the desired pattern on a mask substrate, and the mask substrate on which the pattern is drawn is processed by a mask processing step mainly including development and etching, thereby forming the desired pattern. After that, in a dimension inspection step in step S15, the dimensions of preset monitor patterns are selectively measured to check whether the pattern formed on the mask satisfies the required accuracy. In step S16, whether the results of the dimension measurements satisfy the dimensional accuracy required of the mask is determined.

In step S17, the mask having passed the determination undergoes inspection steps such as mask defect inspection except for the dimension inspection described above, a pellicle is adhered to the mask, and the mask is shipped to a device fabrication site where a semiconductor device is fabricated by using the mask. The mask is rejected, however, if the above dimension measurement results do not satisfy the dimensional accuracy required of the mask. In this case, the series of mask formation steps starting from the pattern drawing step are repeated.

Note that in this mask remaking process, the drawing conditions and the conditions of mask processing mainly including development and etching are sometimes adjusted on the basis of the dimension measurement results.

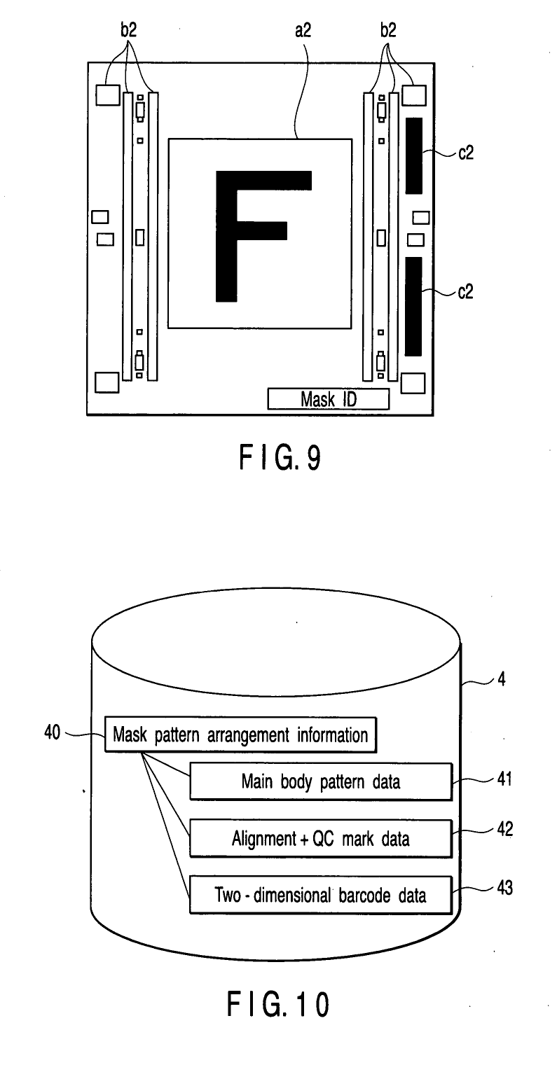

FIG. 9 is a plan view showing the pattern image of the photomask formed by the above steps. Referring to FIG. 9, a portion describing an F mark is an area a2 expressing a desired semiconductor device pattern. An area b2 includes an alignment mark necessary to transfer the photomask formed by the above steps to a semiconductor wafer by an exposure apparatus, and QC marks for monitoring the pattern accuracy independent of a semiconductor device pattern which changes in accordance with a mask. A portion indicated by an area c2 is a two-dimensional barcode formation portion expressing pattern measurement information and dimension acceptability determination information as the gist of this embodiment.

FIG. 10 is a schematic view showing the system of mask drawing data expressing these patterns to be formed on the photomask. As shown in FIG. 10, a disk 4 separately stores main body pattern data 41 expressing the semiconductor device pattern described above, alignment mark and QC mark data 42, and two-dimensional barcode data 43. These pattern data are defined in association with mask pattern arrangement information 40 expressing the drawing positions on the mask.

The two-dimensional barcode data portion will be explained below.

FIG. 11 is a plan view showing the arrangement of two-dimensional barcodes. Referring to FIG. 11, the areas c2 are set as two-dimensional barcode formation areas. The number of characters expressible by one two-dimensional barcode is limited. Therefore, if information cannot be expressed by one two-dimensional barcode or information attributes to be expressed by a two-dimensional barcode are different, a plurality of two-dimensional barcodes are arranged as they are separately defined.

The information attribute is identification information which distinguishes between types of inspection information, e.g., pattern measurement information and dimension acceptability determination information as information to be expressed by two-dimensional barcodes. When information is expressed by a plurality of two-dimensional barcodes, the information is expressed by this information attribute. Information expressed by this two-dimensional barcode will be explained below.

An information system expressed by a two-dimensional barcode includes (1) attribute information representing the information attribute described above, and (2) real data defining entity information such as pattern measurement information and dimension acceptability determination information. Examples of the real data are inspection information such as dimension monitor coordinate values, designed dimensional values, tone information, and measurement pattern shapes.

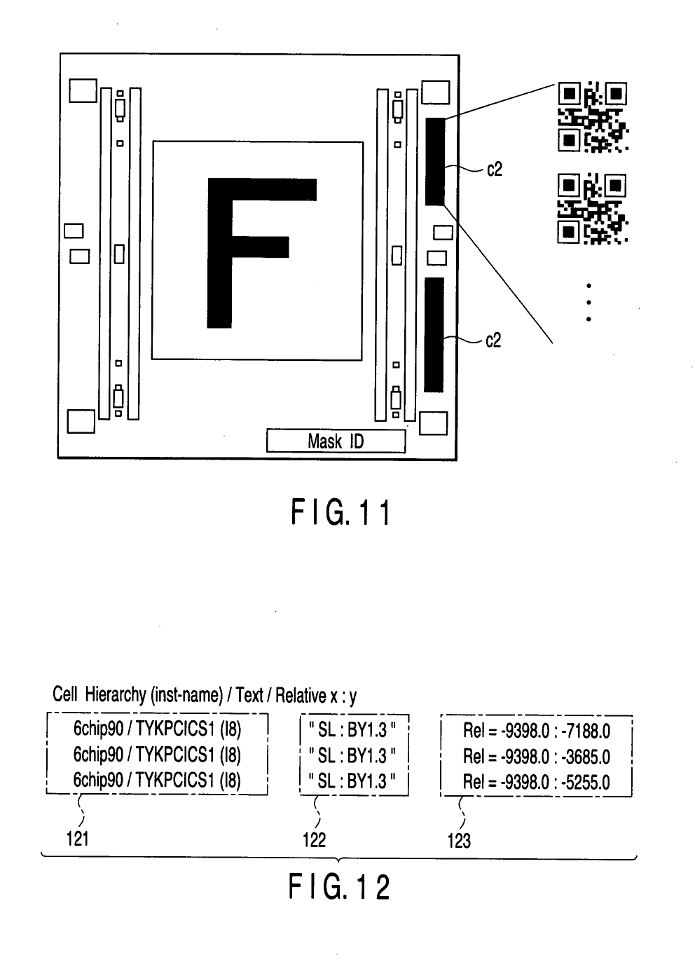

FIG. 12 is a view showing the system of pattern measurement information expressed by the two-dimensional barcode portion. This information shown in FIG. 12 includes a descriptive portion 121 indicating the type (e.g., the dimensional uniformity on the mask surface or the dimensional average between the mask surfaces) of pattern whose dimension is to be measured, a descriptive portion 122 concerning a measurement pattern, and a descriptive portion 123 of measurement pattern coordinates.

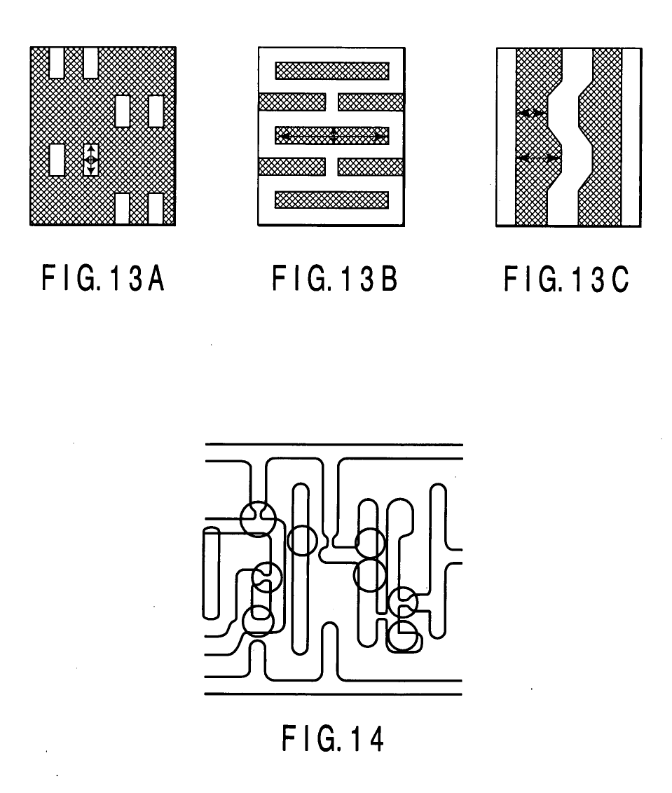

The descriptive portion 122 concerning a measurement pattern is expressed by a keyword (corresponding to SL in the descriptive portion 122 of FIG. 12) for identifying a measurement pattern shape (in this example, a hole shape or line shape pattern) as shown in FIG. 13A, 13B, or 13C, a keyword (corresponding to B in the descriptive portion 122 of FIG. 12) indicating whether a measurement portion of the measurement pattern is a white pattern portion (corresponding to a glass portion) or a black pattern portion (chrome portion or semitransparent film portion), a keyword (corresponding to Y in the descriptive portion 122 of FIG. 12) indicating whether the measurement portion is the X dimension, the Y dimension, or both the X and Y dimensions of the measurement pattern, and a keyword (corresponding to 1.3 in the descriptive portion 122 of FIG. 12) indicating a designed dimensional value when a measurement pattern error is 0. The descriptive portion 123 concerning measurement pattern coordinates expresses the central coordinate values of the measurement pattern portion.

A mask is formed using mask drawing data including two-dimensional barcodes whose information is defined as described above, and a measurement recipe for allowing a dimension measurement apparatus to measure the dimension is formed by reading the pattern measurement information from the two-dimensional barcode portion of the formed mask. A desired pattern is measured in accordance with this measurement recipe, and the dimensional uniformity on the mask surface and the average value of the measured dimensions of the mask are calculated as dimensional offset values of the mask.

As shown in FIG. 11, mask dimension acceptability determination information expressed by two-dimensional barcodes (which are distinguished from two-dimensional barcodes of the pattern measurement information by attribute information) is formed in the two-dimensional barcode formation area c2 of the mask. This barcode information is read to recognize the allowable range of the dimensional uniformity of the mask and the allowable range of the dimensional offset of the mask. These allowable ranges of the dimensional uniformity and dimensional offset are compared with the pattern measurement results of the dimensional uniformity and dimensional offset obtained as described above. In this manner, whether the mask is accepted (in this case, the mask advances to subsequent steps such as defect inspection) or rejected (in this case, the mask will be remade) is determined.

Note that in the mask acceptability determination described above, it is also possible to apply, as one embodiment, a method which adds the measurement results of the phase difference and transmittance of the mask to the measurement results of the dimensional uniformity and dimensional offset, converts the differences between the measurement results and their respective desired values into a deterioration amount when the photomask is exposed and patterned on a semiconductor wafer, and forms, as a pattern in the two-dimensional barcode, a deterioration amount calculating function for determining the acceptability of the mask by checking whether the deterioration amount falls within an allowable range.

FIG. 14 is a view showing the image of critical pattern extraction. As shown in FIG. 14, simulation is performed by assuming exposure conditions when transferring a pattern included in a mask to be formed from the mask to a wafer by an exposure apparatus, and conditions when developing and etching the exposed pattern on the wafer, thereby estimating the influence of a local dimensional fluctuation. A state in which this fluctuation amount is, e.g., 10% or more or a pattern interferes with an adjacent pattern to open (pattern disconnection) or short (pattern connection) is set as a boundary condition, and a portion where a dimensional fluctuation exceeding this boundary condition may occur is extracted. Referring to FIG. 14, circular portions are extracted portions.

A pattern portion concerning the extracted portion is formed into patterns as critical information by using the two-dimensional barcodes shown in FIG. 11, and defined as the critical information by the attribute information of the two-dimensional barcode portion.

Pattern dimension measurement and mask acceptability determination are performed following the same procedures as for the measurements of the dimensional uniformity on the mask surface and the average value of the measured dimensions described above.

When forming a desired pattern on a photomask, the photomask formation method of the second embodiment forms, on the photomask, two-dimensional barcode patterns of dimension management information for assuring dimensions by monitoring the dimensions of the photomask. In the mask inspection step of inspecting whether the dimensions of the semiconductor device pattern formed on the photomask are controlled within a desired allowable range, pattern measurement information for monitoring the mask dimensions is read and identified from the two-dimensional barcode portion formed as patterns on the mask. On the basis of this identification information, the dimensions of a designated pattern portion are measured. In addition, acceptability determination information for determining whether the dimension measurement results fall within a desired allowable range is read and identified from the two-dimensional barcode portion, thereby determining whether the dimensions of the photomask are acceptable.

Conventionally, those information concerning the dimension guarantee positions and guarantee patterns and information for determining the acceptability of a photomask, which are exchanged by a document or communicating means (e.g., computer communication), are circulated through a path different from that of a photomask as an actual fabricated product, and managed independently of the photomask.

Accordingly, if it is necessary to refabricate a once formed photomask owing to an increase in production of semiconductor devices or breakage of the photomask, information concerning dimension guarantee and guarantee patterns for fabrication in the past and information for determining the acceptability of the fabricated photomask must be prepared again when fabricating a mask. This requires much labor and an infrastructure for managing the labor, and hence interferes with labor saving and process simplification in mask fabrication, resulting in a big factor of an increase in cost.

In the second embodiment, however, it is possible to integrally manage drawing data necessary to form a photomask for use in the fabrication of a semiconductor device, and dimension measurement information of a pattern formed on the mask and pattern formation accuracy acceptability determination information based on the dimensional measurement results, and automate dimension measurements and acceptability determination by a dimension measurement apparatus by detecting the dimension measurement information and acceptability determination information from two-dimensional barcodes formed on the mask. Consequently, it is possible to shorten the TAT, save manpower, and reduce the management infrastructure in mask fabrication, thereby largely reducing the mask fabrication cost.

The second embodiment can automate the mask dimension assuring step and rationalize document management pertaining to dimension guarantee.

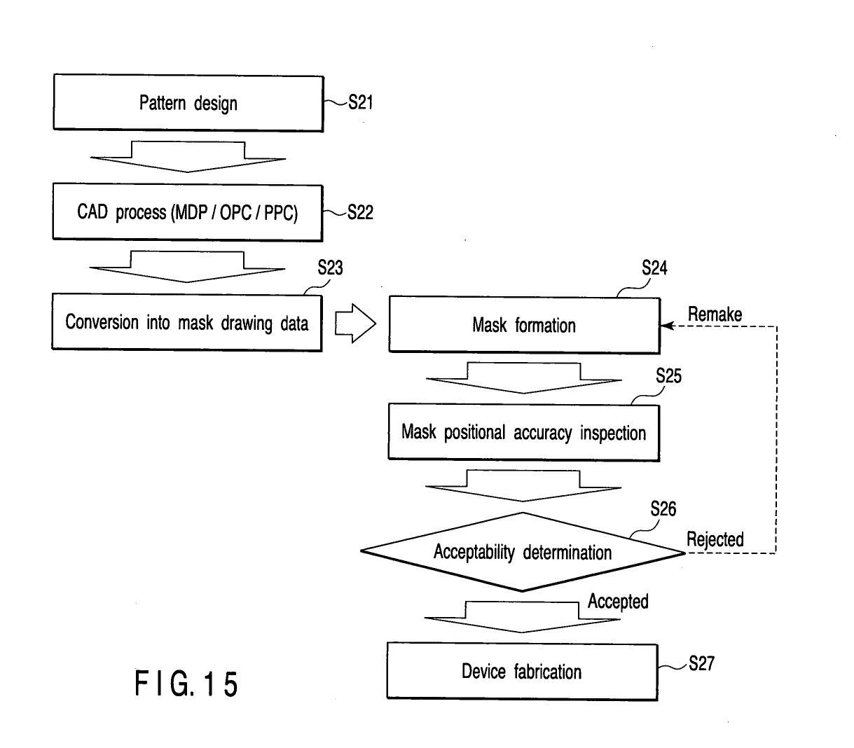

FIG. 15 is a flowchart showing the formation steps of a photomask for use in the fabrication of a semiconductor device according to the third embodiment of the present invention. The following steps include a mask positional accuracy assuring step of inspecting whether the positional accuracy of a pattern formed on the photomask satisfies the desired required accuracy.

First, in step S21, design data is formed by designing a desired pattern for fabricating a semiconductor device. In step S22, a CAD process is performed on the design data. This CAD process is a combination of, e.g., optical proximity effect correction (to be referred to as an OPC process hereinafter) for correcting the optical proximity effect (to be referred to as the OPE hereinafter) when an exposure apparatus transfers the pattern from a photomask onto a wafer, a PPC process for correcting pattern deformation of the wafer caused by the process proximity effect (to be referred to as the PPE hereinafter) which occurs when the exposed pattern is processed by development and etching, an interlayer data operating process (e.g., an AND or OR operation between graphic data) for obtaining pattern data to be formed on the photomask from the design data, a dimension correcting process (to be referred to as resizing hereinafter), and a tone reversing process. In this manner, data of the desired pattern to be formed on a photomask is formed.

In step S23, the data of the desired pattern to be formed on a photomask is converted into mask drawing data which can be input to a pattern drawing (generating) apparatus represented by an electron beam lithography apparatus for use in the fabrication of a mask.

In step S24, the mask drawing data is input to a pattern drawing apparatus represented by an electron beam lithography apparatus to draw the desired pattern on a mask substrate, and the mask substrate on which the pattern is drawn is processed by a mask processing step mainly including development and etching, thereby forming the desired pattern. After that, in a mask positional accuracy inspection step in step S25, the positional accuracies of preset monitor patterns are selectively measured to check whether the position of the pattern formed on the mask satisfies the required accuracy. In step S26, whether the results of the positional accuracy measurements satisfy the positional accuracy required of the mask is determined.

In step S27, the mask having passed the determination undergoes inspection steps such as mask dimension inspection and mask defect inspection except for the positional accuracy inspection described above, a pellicle is adhered to the mask, and the mask is shipped to a device fabrication site where a semiconductor device is fabricated by using the mask. The mask is rejected, however, if the above positional accuracy measurement results do not satisfy the positional accuracy required of the mask. In this case, the series of mask formation steps starting from the pattern drawing step are repeated.

Note that in this mask remaking process, the drawing conditions and the conditions of mask processing mainly including development and etching are sometimes adjusted on the basis of the positional accuracy measurement results.

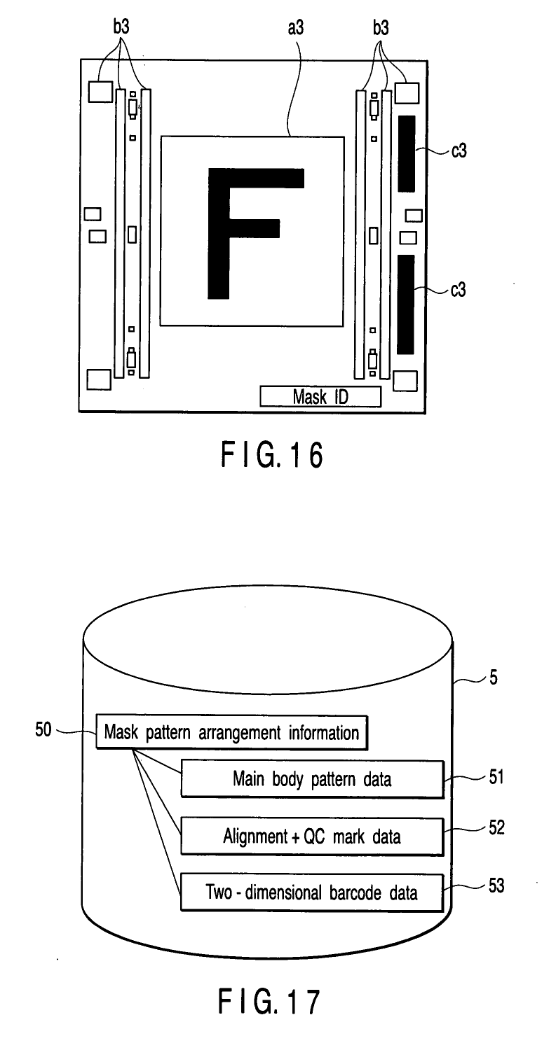

FIG. 16 is a plan view showing the image of the photomask formed by the above steps. Referring to FIG. 16, a portion describing an F mark is an area a3 expressing a desired semiconductor device pattern. An area b3 includes an alignment mark necessary to transfer the photomask formed by the above steps to a semiconductor wafer by an exposure apparatus, and QC marks for monitoring the pattern accuracy independent of a semiconductor device pattern which changes in accordance with a mask. A portion indicated by an area c3 is a two-dimensional barcode formation portion expressing pattern positional accuracy measurement information and positional accuracy acceptability determination information as the gist of this embodiment.

FIG. 17 is a schematic view showing the system of mask drawing data expressing these patterns to be formed on the photomask. As shown in FIG. 17, a disk 5 separately stores main body pattern data 51 expressing the semiconductor device pattern described above, alignment mark and QC mark data 52, and two-dimensional barcode data 53. These pattern data are defined in association with mask pattern arrangement information 50 expressing the drawing positions on the mask.

The two-dimensional barcode data portion will be explained below.

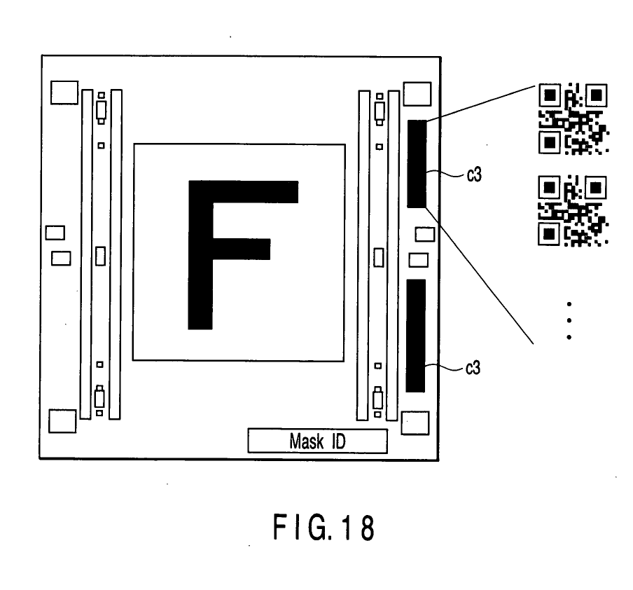

FIG. 18 is a plan view showing the arrangement of two-dimensional barcodes. Referring to FIG. 18, the areas c3 are set as two-dimensional barcode formation areas. The number of characters expressible by one two-dimensional barcode is limited. Therefore, if information cannot be expressed by one two-dimensional barcode or information attributes to be expressed by a two-dimensional barcode are different, a plurality of two-dimensional barcodes are arranged as they are separately defined.

The information attribute is identification information which distinguishes between types of inspection information, e.g., pattern positional accuracy measurement information and positional accuracy acceptability determination information as information to be expressed by two-dimensional barcodes. When information is expressed by a plurality of two-dimensional barcodes, it is done by this information attribute. Information expressed by this two-dimensional barcode will be explained below.

An information system expressed by a two-dimensional barcode includes (1) attribute information representing the information attribute described above, and (2) real data defining inspection information such as measurement mark position information for measuring the positional accuracy, measurement mark width and measurement mark tone information, and acceptability determination information on the magnification, orthogonality, offset, and rotation components calculated on the basis of the measured measurement mark position and the residual component derived by excluding these shaping components.

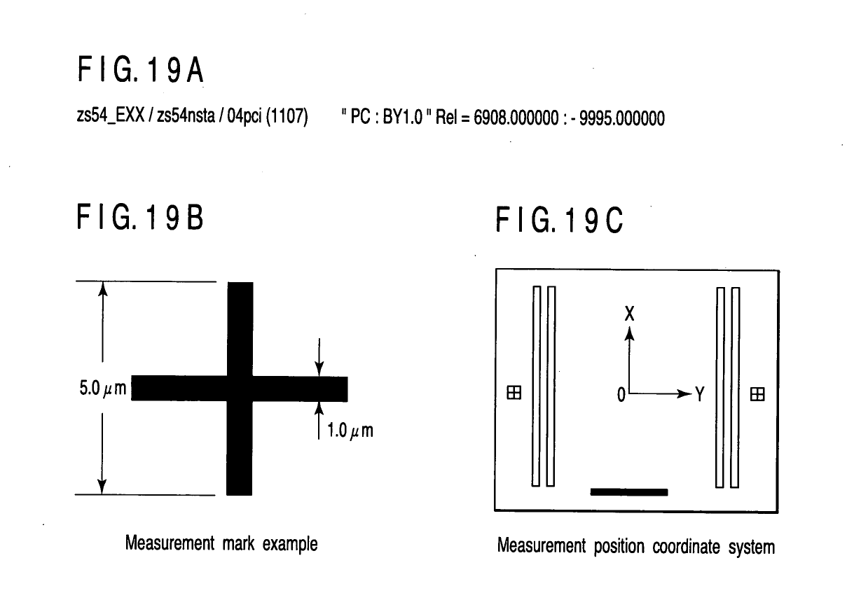

FIG. 19A is a view showing the system of positional accuracy measurement information expressed by the two-dimensional barcode portion. FIG. 19B is a view showing an example of a measurement mark. FIG. 19C is a view showing a measurement position coordinate system on a mask. The information shown in FIG. 19A is positional accuracy measurement information as a set of pieces of information concerning one mark measurement and formed by coded information which identifies whether a measurement mark whose position is to be measured is a blank pattern (white=glass portion) or a solid pattern (black=light-shielding film portion), coded information expressing the pattern width of the measurement mark, and coded information indicating the position of the measurement mark on drawing pattern data. This information is expressed in a text form or encrypted form in the two-dimensional barcode portion, and formed as patterns on a mask. Referring to FIG. 19A, “B” indicates that the measurement pattern is black, “1.0” indicates that the size of the measurement pattern is 1.0 μm, and “Rel=6908.000000:-9995.000000” indicates the measurement position [μm] when the wafer center is the origin.

A mask is formed using mask drawing data including two-dimensional barcodes whose information is defined as described above, and a measurement recipe for allowing a positional accuracy measurement apparatus to measure the positional accuracy of a pattern portion in which the series of measurement marks described above are actually formed on the mask is formed by reading the pattern measurement information from the two-dimensional barcode portion of the formed mask. The positional accuracy of the mask is calculated by performing desired pattern position measurement in accordance with this measurement recipe.

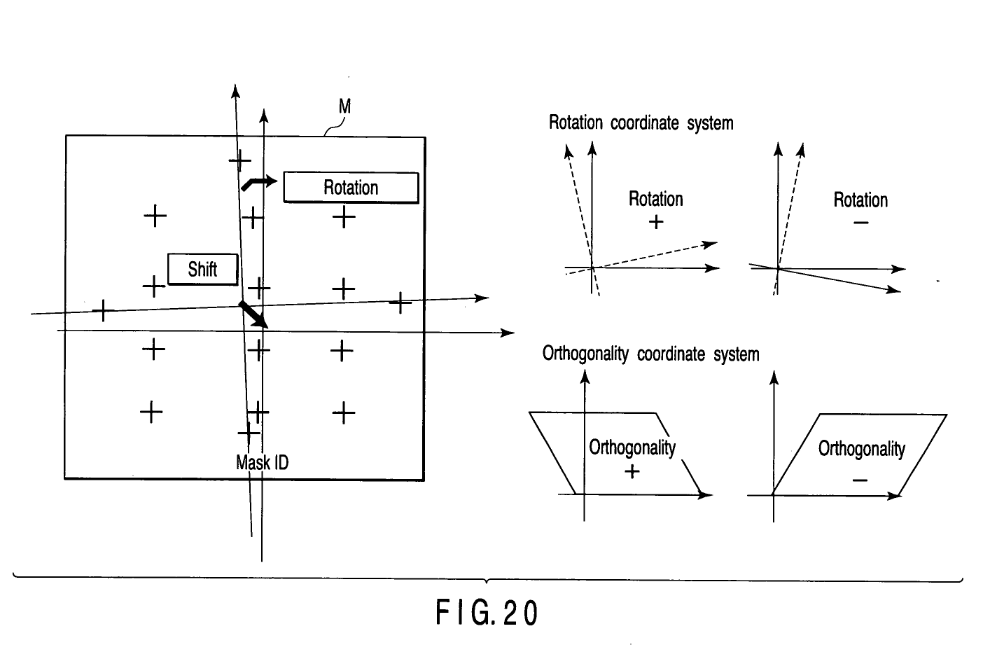

More specifically, pattern position measurement is performed on cross-shaped positional accuracy measurement marks arranged on the mask surface as shown in FIG. 20. From the differences between the measured measurement position data and the ideal positions of the measurement marks defined in drawing pattern data, the magnification (x,y), orthogonality, offset (x,y), and rotation of the formed mask and the residual component are derived. The residual component is a random error component obtained by excluding, from the error components described above, the magnification and orthogonality as linear components correctable by an exposure apparatus for wafer exposure.

As shown in FIG. 18, as these pattern positional accuracy measurement results, mask positional accuracy acceptability determination information expressed by two-dimensional barcodes (which are distinguished from two-dimensional barcodes of the pattern positional accuracy measurement information by attribute information) is formed in the two-dimensional barcode formation area c3 of the mask. This barcode information is read to compare the allowable range of the positional accuracy of the mask with the pattern positional accuracy measurement results. In this manner, whether the mask is accepted (in this case, the mask advances to subsequent steps such as defect inspection) or rejected (in this case, the mask will be remade) is determined.

Note that in the mask acceptability determination described above, it is also possible to apply, as one embodiment, a method which converts the positional accuracy measurement results into a deterioration amount when the photomask is exposed and patterned on a semiconductor wafer, and forms, as a pattern in the two-dimensional barcode, a deterioration amount calculating function for determining the acceptability of the mask by checking whether the deterioration amount falls within an allowable range.

When forming a desired pattern on a photomask, the photomask formation method of the third embodiment forms, on the photomask, two-dimensional barcode patterns of position management information for assuring the pattern positional accuracy of the photomask by monitoring. In the mask inspection step of inspecting whether the position of the semiconductor device pattern formed on the photomask is controlled within a desired allowable range, pattern measurement information for monitoring the mask positional accuracy is read and identified from the two-dimensional barcode portion formed as patterns on the mask. On the basis of this identification information, the positional accuracy of a designated pattern portion is measured. In addition, acceptability determination information for determining whether the measured positional accuracy falls within a desired allowable range is read and identified from the two-dimensional barcode portion, thereby determining the acceptability of the positional accuracy of the photomask.

Conventionally, positional accuracy measurement information and acceptability determination information exchanged by a document or communicating means (e.g., computer communication) are circulated through a path different from that of a photomask as an actual fabricated product, and managed independently of the photomask.

Accordingly, if it is necessary to refabricate a once formed photomask owing to an increase in production of semiconductor devices or breakage of the photomask, positional accuracy measurement information and information for acceptability determination for fabrication in the past must be prepared again when fabricating a mask. This requires much labor and an infrastructure for managing the labor, and hence interferes with labor saving and process simplification in mask fabrication, resulting in a big factor of an increase in cost.

In the third embodiment, however, it is possible to integrally manage drawing data necessary to form a photomask for use in the fabrication of a semiconductor device, and positional accuracy measurement information of a pattern formed on the mask and pattern positional accuracy acceptability determination information based on the positional accuracy measurement results, and automate positional accuracy measurements and acceptability determination by a positional accuracy measurement apparatus by recognizing the positional accuracy measurement information and acceptability determination information from a two-dimensional barcode portion formed on the mask. Consequently, it is possible to shorten the TAT, save manpower, and reduce the management infrastructure in mask fabrication, thereby largely reducing the mask fabrication cost.

The third embodiment can automate the mask positional accuracy assuring step and rationalize document management pertaining to positional accuracy guarantee.

The use of a photomask prepared in the above-described manner to form a circuit pattern on a semiconductor substrate makes it possible to fabricate a semiconductor device.

This embodiment can provide a photomask formation method, photomask, and semiconductor device fabrication method capable of saving manpower and reducing the cost in the fabrication of a photomask.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A photomask formation method comprising:
forming, on a photomask, a pattern obtained by coding information including inspection information for inspecting the photomask and an information attribute which identifies a type of the inspection information;
reading the inspection information from the pattern; and
inspecting the photomask on the basis of the read inspection information.

2. The method according to claim 1, wherein the pattern comprises a two-dimensional barcode.

3. The method according to claim 2, wherein a plurality of the two-dimensional barcodes are arranged when information is not expressed by one two-dimensional barcode or information attributes to be expressed by a two-dimensional barcode are different.

4. The method according to claim 1, wherein the inspection information includes information pertaining to defect inspection.

5. The method according to claim 4, wherein the information pertaining to defect inspection includes inspection area information, inspection sensitivity information, and inspection comparison method information.

6. The method according to claim 5, wherein the inspection comparison method information indicates a die-to-die method.

7. The method according to claim 5, wherein the inspection comparison method information indicates a die-to-database method.

8. The method according to claim 1, wherein the inspection information includes information pertaining to dimension inspection.

9. The method according to claim 8, wherein the information pertaining to dimension inspection includes dimension measurement information and dimension acceptability determination information.

10. The method according to claim 1, wherein the inspection information includes information pertaining to positional accuracy inspection.

11. The method according to claim 10, wherein the information pertaining to positional accuracy inspection includes positional accuracy measurement information and positional accuracy acceptability determination information.

12. A photomask comprising a pattern obtained by coding information including inspection information for inspecting the photomask and an information attribute which identifies a type of the inspection information.

13. The photomask according to claim 12, wherein the pattern comprises a two-dimensional barcode.

14. The photomask according to claim 13, wherein a plurality of the two-dimensional barcodes are arranged when information is not expressed by one two-dimensional barcode or information attributes to be expressed by a two-dimensional barcode are different.

15. The photomask according to claim 12, wherein the inspection information includes, as information pertaining to defect inspection, inspection area information, inspection sensitivity information, and inspection comparison method information.

16. The photomask according to claim 12, wherein the inspection information includes, as information pertaining to dimension inspection, dimension measurement information and dimension acceptability determination information.

17. The photomask according to claim 12, wherein the inspection information includes, as information pertaining to positional accuracy inspection, positional accuracy measurement information and positional accuracy acceptability determination information.

18. A semiconductor device fabrication method of fabricating a semiconductor device by reading inspection information from a pattern formed on a photomask, the pattern being obtained by coding information including the inspection information for inspecting the photomask and an information attribute which identifies a type of the inspection information, and forming a circuit pattern on a semiconductor substrate by using the photomask inspected on the basis of the read inspection information.
